(19) United States
(12) Patent Application Publication
(10) Pub. No.: US 2003/0087502 A1
(43) Pub. Date: May 8, 2003

(54) Carrier for used in manufacturing semiconductor encapsulant packages

(75) Inventors: Yu-Wen Chen, Kaoshiung (TW); Wann-Lung Chien, Kaoshiung (TW)

Correspondence Address: Ladas & Parry, 26 West 61st Street, New York, NY, 10023, US

(73) Assignee: ADVANCED SEMICONDUCTOR ENGINEERING, INC.

(21) Appl. No.: 10/056,361

(22) Filed: Jan. 25, 2002

(30) Foreign Application Priority Data
Nov. 2, 2001 (TW) 90127310

(51) Int. Cl. H01L 21/76

(52) U.S. Cl. 438/406

(57) ABSTRACT

The present invention relates to a carrier for used in manufacturing semiconductor encapsulant packages. The carrier comprises at least one receiving part and a plurality of positioning pins; wherein the receiving part is used in receiving the semiconductor encapsulant package, and the positioning pins protrude upwards from an edge of the receiving part for used in positioning the semiconductor encapsulant package on the carrier; and each positioning pin is at an obtuse angle θ to the receiving part. The present invention can prevent an encapsulant from contacting with the positioning pins and avoid leakage when applying the encapsulant. Additionally, the present invention also broadens available areas of substrates for packaging. Furthermore, the carrier in the present invention is integrally formed and has a advantage of being produced and controlled easily.

### BACKGROUND OF THE INVENTION

1. Field of the Invention

The present invention relates to a semiconductor encapsulant package, more particularly, to a carrier for used in manufacturing semiconductor encapsulant packages.

2. Description of the Related Art

Among various kinds of semiconductor encapsulant packages, packaging a substrate and electric elements thereon by applying an encapsulant is one of forms utilized broadly. The substrate used in such form of package is usually dielectric, for example, plastic or ceramic, and electric elements and dies are allowed to be printed or set thereon. There may be one or more element sets packaged on one substrate. If more than one element sets packaged on one substrate, an encapsulant is first applied on the substrate and then cut after package.

When manufacturing such packages, a carrier is necessary for receiving the substrates to be applied with the encapsulant and/or cut later.

FIG. 1 is a cross-sectional view of a conventional carrier for used in manufacturing semiconductor encapsulant packages. The carrier 1 used for receiving a substrate 5 and a die 6 thereon comprises at least one receiving part 12; wherein each one of the receiving part 12 receives the substrate 5 and the die 6 thereon. In order to satisfy the requirement of manufacture on a large scale, a plurality of semiconductor encapsulant packages with the substrates 5 and dies 6 thereon are co-placed on one carrier. Each substrate 5 is placed on one receiving part 12, and each receiving part 12 connects with adjacent ones through a carrier main body 11; wherein the carrier main body 11 comprises constructions enabling the carrier 1 to be applied to machines in manufacture. In order to work accurately by machines, the substrate 5 should be located in appropriate positions on the carrier 1. For this reason, the carrier 1 further comprises a plurality of positioning pins 13. Each of the positioning pins 13 is a rectangular body protruding vertically upwards from an edge of the receiving part 12. Positions and numbers of such positioning pins are unlimited as long as the positioning pins can provide positioning functions.

After the substrate 5 and the die 6 thereon put on the carrier 1, an encapsulant can be applied. The encapsulant is first applied along edges nearby on a surface of the substrate 5, and then to coat the whole surface of the substrate 5. The encapsulant can take advantages of surface tension and cohesion itself to reach edges of the substrate 5 from sites of applying, and form an encapsulant 7.

Because the positioning pin 13 is at an angle of about or less than 90° to the receiving part 12, the encapsulant may contact with the positioning pin 13 directly when applying the encapsulant. Thus, the encapsulant may leak along the positioning pin 13 to a backside of the substrate 5 and the receiving part 12, and pollute the substrate 5 if quantity or quality of the encapsulant is not well controlled. Such a condition described above also makes the removal of products from the carrier 1 difficult after packaging completed. In addition, when setting the dies 6, an appropriate size of margin should be kept to prevent from insulation resulting from a contact between the encapsulant and electric elements on the backside of the substrate 5 in view of leakage of the encapsulant. Therefore, available areas of the substrate 5 are not large and costs of manufacture rise indirectly at the same time.

In order to overcome problems of the encapsulant leaking along the positioning pin 13 mentioned above, other designs of positioning pin have been developed in this field. Referring to a carrier 2 shown in FIG. 2, the carrier 2 is used for receiving a substrate 5 and a die 6 thereon. The carrier 2 comprises at least one receiving part 22 and a plurality of positioning pins 23; wherein a surface of the positioning pin 23 facing to the substrate 5 is arched. The positioning pin 23 still partially contacts with the substrate 5 in such design. In the process of applying an encapsulant, leaking along the positioning pin 23 still occurs. However, by the design of arched surface, the encapsulant will leak to a space formed by the positioning pin 23, the receiving part 22 and the substrate 5 instead, and it reduces chances of pollution on a backside of the substrate. On the other hand, in the manufacture of the carrier 2, it is difficult to control conditions of forming an arched surface, and relatively arises difficulties of manufacture.

Therefore, it is desirable to provide an easily made carrier for manufacturing semiconductor encapsulant packages to overcome leakage pollutions when packaging by applying an encapsulant and to broaden available areas of a substrate for packaging.

### SUMMARY OF THE INVENTION

The main objective of the present invention is to provide a carrier for manufacturing semiconductor encapsulant packages. The carrier comprises at least one receiving part and a plurality of positioning pins; wherein the receiving parts receive the semiconductor encapsulant package; each of the positioning pins protrudes upwards from edges of the receiving part for positioning the semiconductor encapsulant package on the carrier; and each positioning pin is at an obtuse angle to the receiving part. The present invention can prevent an encapsulant from contacting with the positioning pins and avoid leakage in the process of applying. Additionally, the present invention also broadens available areas of substrates for packaging. Furthermore, the carrier in the invention is integrally formed and has a advantage of being produced and controlled easily.

### BRIEF DESCRIPTION OF THE DRAWINGS

FIG. 1 is a cross-sectional view illustrating a conventional carrier receiving a semiconductor encapsulant package for used in manufacturing semiconductor encapsulant packages;

FIG. 2 is another cross-sectional view illustrating a conventional carrier receiving a semiconductor encapsulant package for used in manufacturing semiconductor encapsulant packages;

FIG. 3 is a cross-sectional view illustrating a carrier for used in manufacturing semiconductor encapsulant packages according to the first embodiment of the invention, wherein a semiconductor encapsulant package is mounted thereon;

FIG. 4 is a cross-sectional view illustrating a carrier for used in manufacturing semiconductor encapsulant packages according to the second embodiment of the invention, wherein a semiconductor encapsulant package is mounted thereon; and

FIGS. 5a to 5c are cross-sectional views illustrating the operation of the carrier for used in manufacturing semiconductor encapsulant packages according to the first embodiment of the invention, wherein the continuous steps of mounting the semiconductor encapsulant package on the carrier are shown.

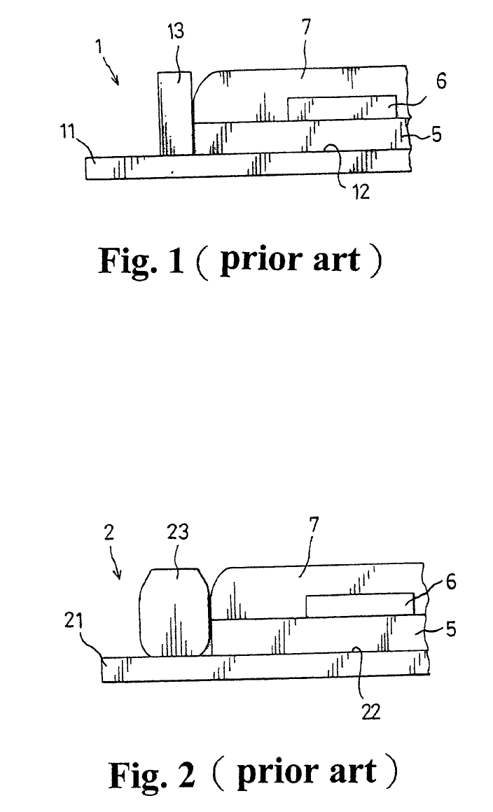

### DETAILED DESCRIPTION OF THE INVENTION

The present invention relates to a carrier for used in manufacturing semiconductor encapsulant packages in order to minimize an encapsulant leakage pollution of substrates when applying.

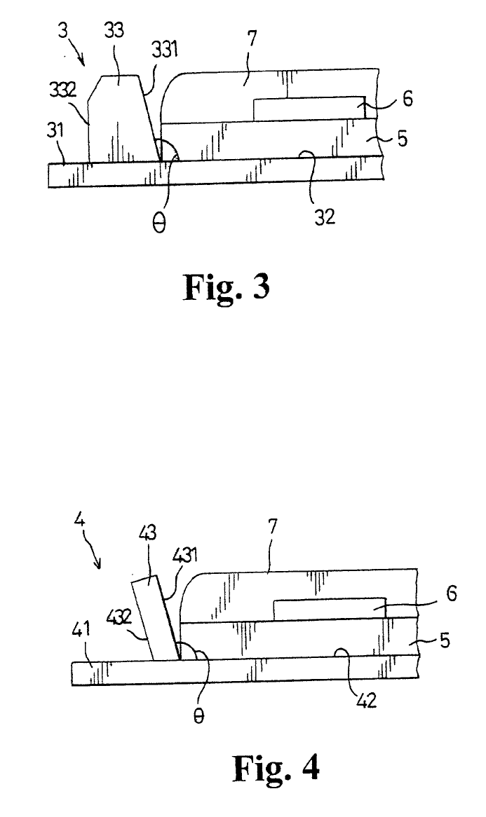

FIG. 3 shows a carrier 3 in the first embodiment of the invention. The carrier 3 used for receiving a substrate 5 and a die 6 thereon comprises at least one receiving part 32 and a plurality of positioning pins 33. The receiving part 32 contacts with a semiconductor encapsulant package (which comprises the substrate 5 and the die 6 thereon) for receiving the package. Each of the positioning pins 33 protrudes upwards from an edge of the receiving part 32 for positioning the semiconductor encapsulant package on the carrier 3. Positions and numbers of such positioning pin 33 are unlimited as long as the positioning pins can provide positioning functions. Furthermore, the carrier 3 further comprises a carrier main body 31 used in connection when the carrier 3 receives a plurality of semiconductor encapsulant packages, and the carrier main body 31 comprises constructions that enable the carrier 3 to be applied to machines in manufacture.

The invention is characterized by providing the positioning pin that is at an obtuse angle θ to the receiving part; wherein the angle θ is larger than 91°. Referring to FIG. 3, in the first embodiment of the invention, a first plane 331 of the positioning pin 33 facing to the substrate 5 is slant; wherein the first plane 331 is at an angle θ to the receiving part 32 and the angle θ is larger than 91°, for example, 92°, 93°, 95°, or 105°. On the other hand, a second plane 332 of the positioning pin 33 opposite the substrate 5 is vertical and at an angle of about 90° to the receiving part 32.

FIG. 4 shows a carrier 4 in the second embodiment of the invention. The carrier 4 used for receiving a substrate 5 and a die 6 thereon comprises at least one receiving part 42 and a plurality of positioning pins 43. The positioning pin 43 comprises a first plane 431 facing to the substrate 5; wherein the first plane 431 of the positioning pin 33 is at an angle θ to the receiving part 42 and the angle θ is larger than 91°, for example, 92°, 93°, 95°, or 105°. On the other hand, opposite the substrate 5 of the positioning pin 43 is a second plane 432; wherein the second plane 432 is substantially parallel to the first plane 431.

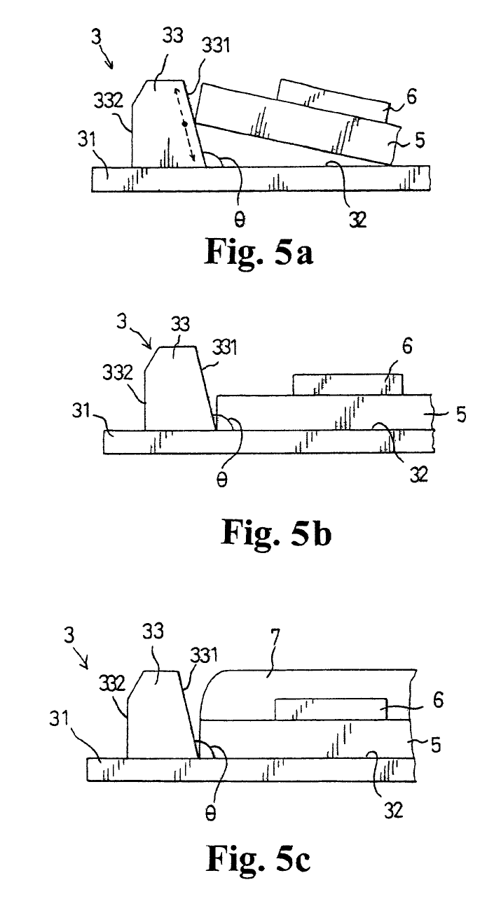

FIGS. 5a to 5c show continuous steps of mounting the semiconductor encapsulant package on the carrier 3 in the first embodiment of the invention. In FIG. 5a, because the first plane 331 of the positioning pin 33 faces to the substrate 5, the substrate 5 may contact with the first plane 331 the positioning pin 33 when placing the substrate 5 onto the carrier 3. Therefore, along the first plane 331, an upward friction force exerts between the first plane 331 of the positioning pin 33 and the substrate 5. On the other hand, because of weights of the substrate 5 and the die 6 thereon, a downward gliding force exerts along the first plane 331. The friction force and the gliding force in counter directions are functions of the angle θ. The more the angle θ approaches to 90°, the larger the gliding force will be, and the substrate 5 will easier glide to the receiving part 32. On the other hand, the more the angle θ approaches to 180°, the more the substrate 5 will likely stay on the positioning pin 33. The angle θ in the present invention is what makes the friction force larger than the gliding force, and enables the substrate 5 and the die 6 thereon gliding to the receiving part 32 successfully (referring to FIG. 5b).

For the purpose of the positioning pins 33 functioning positioning and avoiding an encapsulant leaking along the positioning pins 33 in the process of applying, the angle θ between the positioning pin 33 and the receiving part 32 should be obtuse, preferably larger than 91°. In such situation, the encapsulant can take advantages of surface tension and cohesion itself to form an encapsulant 7 on the substrate 5, and avoid leakage resulting from a contact with the positioning pin 33; therefore, it protects a backside of the substrate 5 from pollution (referring FIG. 5c). Furthermore, because no encapsulant leaks to the backside of the substrate 5, it is unnecessary to keep an appropriate size of margin of the substrate 5 for printing or setting electric elements, and thus, available areas of the substrate 5 will be broadened.

In conclusion, the obtuse angle θ between the positioning pin and the receiving part is preferably between 91° and 110°, more preferably between 91° and 96° in the invention.

The manufacture of the carrier in the present invention is quite easy as well. The positioning pins containing simple slants and angles are integrally formed. Thus, cost and difficulty of manufacture will not be raised.

The present invention can be applied in all kinds of forms of applying an encapsulant to package a semiconductor encapsulant, and not limited in any forms of substrates or dies. Persons skilled in the art can easily design the receiving parts and the positioning pins as desired. Furthermore, shapes of positioning pins are not limited in the disclosures in the embodiments. The carriers with obtuse angles between positioning pins and receiving parts are in the scope of the invention.

While embodiments of the present invention have been illustrated and described, various modifications and improvements can be made by those skilled in the art. The embodiments of the present invention are therefore described in an illustrative but not restrictive sense. It is intended that the present invention is not limited to the particular forms as illustrated, is and that all the modifications not departing from the spirit and scope of the present invention are within the scope as defined in the appended claims.

What is claimed is:

1. A carrier for used in manufacturing a semiconductor encapsulant package, which comprises:
at least one receiving part for used in receiving the semiconductor encapsulant package; and
a plurality of positioning pins protruding upwards from an edge of the receiving part for used in positioning the semiconductor encapsulant package on the carrier; wherein an obtuse angle θ is between the positioning pin and the receiving part.

2. The carrier as claimed in claim 1, wherein the semiconductor encapsulant package exerts a friction force and a gliding force when contacting with the positioning pins, and the obtuse angle θ between the positioning pin and the receiving part allows the friction force larger than the gliding force.

3. The carrier as claimed in claim 1, wherein the obtuse angle θ between the positioning pin and the receiving part is larger than 91°.

4. The carrier as claimed in any of claims 1, 2 and 3, wherein the obtuse angle θ between the positioning pin and the receiving part is from 91° to 110°.

5. The carrier as claimed in any of claims 1, 2 and 3, wherein the obtuse angle θ between the positioning pin and the receiving part is from 91° to 96°.

6. The carrier as claimed in claim 1, wherein a first plane of the positioning pin facing the semiconductor encapsulant package is slant and a second plane of the positioning pin opposite the semiconductor encapsulant package is vertical, and wherein the second plane of the positioning pin is at an angle of about 90° to the receiving part.

7. The carrier as claimed in claim 1, wherein a first plane of the positioning pins facing the semiconductor encapsulant package is slant and a second plane of the positioning pin opposite the semiconductor encapsulant package is also slant; wherein the second plane is substantially parallel to the first plane.

8. The carrier as claimed in claim 1, wherein the positioning pins and the receiving parts are integrally formed.
